(19) United States
(12) Patent Application Publication
(10) Pub. No.: US 2011/0259403 A1
(43) Pub. Date: Oct. 27, 2011

(54) PHOTOVOLTAIC DEVICE AND MANUFACTURING THEREOF

(76) Inventors: Seung-Yeop Myong, Seoul (KR); Jun Hyoung Park, Daejon (KR)

(21) Appl. No.: 13/043,538

(22) Filed: Mar. 9, 2011

(30) Foreign Application Priority Data
Apr. 22, 2010 (KR) 10-2010-0037214

(51) Int. Cl. H01L 31/05; H01L 31/18

(52) U.S. Cl. 136/249; 438/73; 257/E31.001

(57) ABSTRACT

Disclosed is a method for manufacturing a photovoltaic device. The method comprises forming a first electrode, a photoelectric conversion layer and a second electrode on a substrate sequentially; forming an insulating layer covering the second electrode; forming a first trench line and a second trench line in the insulating layer on the second electrode such that the second electrode is exposed, wherein at least two photovoltaic cells are included between the first trench line and the second trench line; and forming a first conductive bus bar and a second conductive bus bar by filling the first and the second trench lines with a conductive material.

### CROSS REFERENCE TO RELATED APPLICATIONS

This application claims priority under 35 U.S.C. §119 to Korean Patent Application No. 10-2010-0037214 filed on Apr. 22, 2010, the entirety of which is hereby incorporated by reference.

### FIELD OF THE INVENTION

The present invention relates to a photovoltaic device and a manufacturing method thereof.

### BACKGROUND OF THE INVENTION

Recently, as existing energy resources like oil and coal and the like are expected to be exhausted, much attention is increasingly paid to alternative energy sources which can be used in place of the existing energy sources. As an alternative energy source, sunlight energy is abundant and has no environmental pollution. Therefore, more and more attention is paid to the sunlight energy.

A photovoltaic device, that is, a solar cell directly converts sunlight energy into electric energy. The photovoltaic device mainly uses photovoltaic effect of semiconductor junction. In other words, when light is incident on and absorbed by a semiconductor p-i-n junction doped with p-type impurity and n-type impurity respectively, light energy generates electrons and holes within the semiconductor and the electrons and the holes are separated from each other by an internal field. As a result, a photo-electro motive force is generated between both ends of the p-i-n junction. Here, if electrodes are formed at both ends of the junction and connected with wires, electric current flows externally through the electrodes and the wires.

### SUMMARY OF THE INVENTION

One aspect of the present invention is a manufacturing method of a photovoltaic device. The method comprises forming a first electrode, a photoelectric conversion layer and a second electrode on a substrate sequentially; forming an insulating layer covering the second electrode; forming a first trench line and a second trench line in the insulating layer on the second electrode such that the second electrode is exposed, wherein at least two photovoltaic cells are included between the first trench line and the second trench line; and forming a first conductive bus bar and a second conductive bus bar by filling the first and the second trench lines with a conductive material.

Another aspect of the present invention is a photovoltaic device. The photovoltaic device comprises a photovoltaic substrate formed by sequentially stacking a first electrode, a photoelectric conversion layer and a second electrode on a substrate; an insulating layer being formed on the photovoltaic substrate and comprising a first trench line and a second trench line which have a depth reaching the surface of the second electrode; and a first conductive bus bar and a second conductive bus bar formed by filling a conductive material into the first and the second trench lines, wherein at least two photovoltaic cells are included between the first trench line and the second trench line.

### BRIEF DESCRIPTION OF THE DRAWINGS

FIGS. 1a to 1g are views for describing a method for manufacturing a photovoltaic substrate of a photovoltaic device according to an embodiment of the present invention.

FIGS. 2a to 2d are views for describing a method for manufacturing an insulating layer of a photovoltaic device according to an embodiment of the present invention.

FIGS. 3a to 3c are views for describing a photovoltaic device and a method for manufacturing the photovoltaic device according to a first embodiment of the present invention.

FIG. 4 is a view for describing a photovoltaic device and a method for manufacturing the photovoltaic device according to a second embodiment of the present invention.

FIGS. 5a to 5b are views for describing a photovoltaic device and a method for manufacturing the photovoltaic device according to a third embodiment of the present invention.

FIG. 6 is a view for describing a photovoltaic device and a method for manufacturing the photovoltaic device according to a fourth embodiment of the present invention.

FIGS. 7a to 7d are views for describing a photovoltaic device and a method for manufacturing the photovoltaic device according to a fifth embodiment of the present invention.

FIGS. 8a to 8d are views for describing a photovoltaic device and a method for manufacturing the photovoltaic device according to a sixth embodiment of the present invention.

FIGS. 9a to 9g are views for describing a photovoltaic device and a method for manufacturing the photovoltaic device according to a seventh embodiment of the present invention.

### DETAILED DESCRIPTION

Hereinafter, the present invention will be described with reference to the accompanying drawings. In description of the present invention, what is apparent to those skilled in the art will be omitted in order to avoid making the subject matter of the present invention unclear. Terms to be described below are used only for providing the understanding of the present invention. It is noted that each of manufacturing companies and research groups may use different terms for the same item.

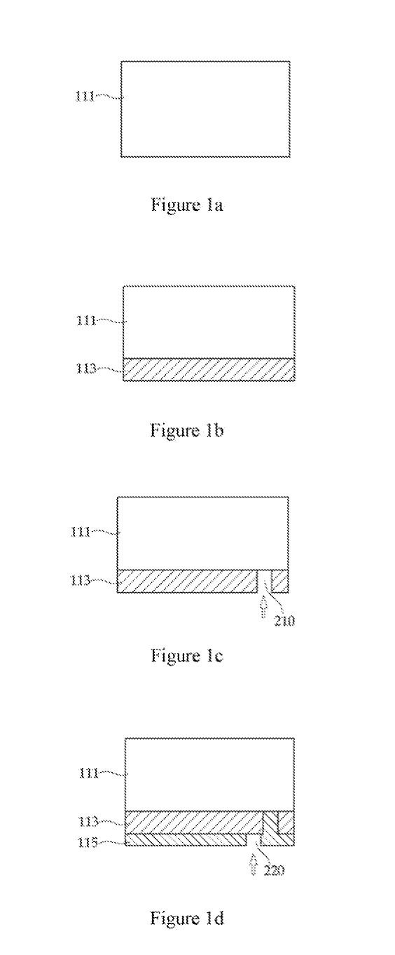

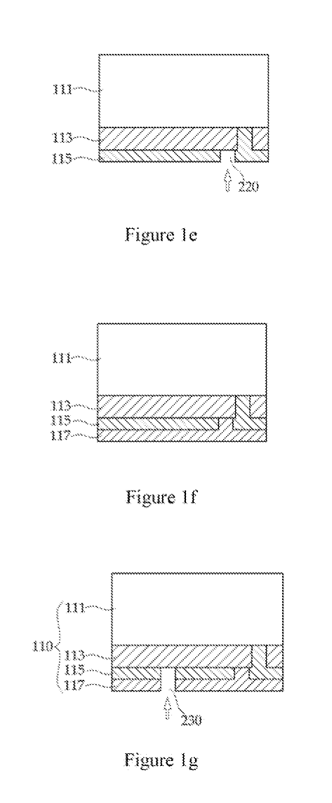

FIGS. 1a to 1g are views for describing a method for manufacturing a photovoltaic substrate of a photovoltaic device according to an embodiment of the present invention. As shown in FIG. 1a, a substrate 111 is provided. The substrate 111 may be an insulating transparent substrate 111.

As shown in FIG. 1b, a first electrode 113 is formed on the substrate 111. In an embodiment of the present invention, the first electrode 113 may be formed by using a chemical vapor deposition (CVD) method and formed of a transparent conductive oxide (TCO) such as SnO₂ or ZnO.

As shown in FIG. 1c, the first electrode 113 is scribed by irradiating a laser beam onto the first electrode 113 or the substrate 11. First separation grooves 210 are hereby formed in the first electrode 113. That is, since the first separation grooves 210 penetrate the first electrode 113, it is possible to prevent short-circuit between the adjacent first electrodes 113.

As shown in FIG. 1d, a photoelectric conversion layer 115 is formed by a CVD method such that the first electrode 113 and the first separation groove 210 are covered with the photoelectric conversion layer 115. Here, in the photoelectric conversion layer 115, a p-type semiconductor layer, an intrinsic semiconductor layer and an n-type semiconductor layer may be sequentially stacked in the order listed. For forming the p-type semiconductor layer, a source gas including silicon such as SiH₄ and a doping gas including group 3 elements such as B₂H₆ are injected together into a reaction chamber, and the p-type semiconductor layer is formed according to a CVD method. Then, when the only source gas including silicon is introduced into the reaction chamber, the intrinsic semiconductor layer is formed on the p-type semiconductor layer. Finally, when a doping gas including group 5 elements such as PH₃ and a source gas including silicon are injected together, and then the n-type semiconductor layer is formed on the intrinsic semiconductor by a CVD method. As a result, the photoelectric conversion layer 115 located on the first electrode 113 includes an amorphous semiconductor layer in which the p-type semiconductor layer, the intrinsic semiconductor layer and the n-type semiconductor layer are stacked in the order listed.

As shown in FIG. 1e, a laser beam is irradiated onto the substrate 111 or the photoelectric conversion layer 115 in the air, so that the photoelectric conversion layer 115 is scribed. Accordingly, second separation grooves 220 are formed in the photoelectric conversion layer 115.

As shown in FIG. 1f, a second electrode 117 covering the photoelectric conversion layer 115 and the second separation groove 220 is formed by a CVD method or a sputtering method. The second electrode 117 may include a metal electrode such as Al or Ag.

As shown in FIG. 1g, the photoelectric conversion layer 115 and the second electrode 117 are scribed by irradiating a laser beam in the air. Accordingly, third separation grooves 230 are formed in the photoelectric conversion layer 115 and the second electrode 117. Through the manufacturing method shown FIGS. 1a to 1g, provided is a photovoltaic substrate 110 including the substrate 111, the first electrode 113, the photoelectric conversion layer 115 and the second electrode 117.

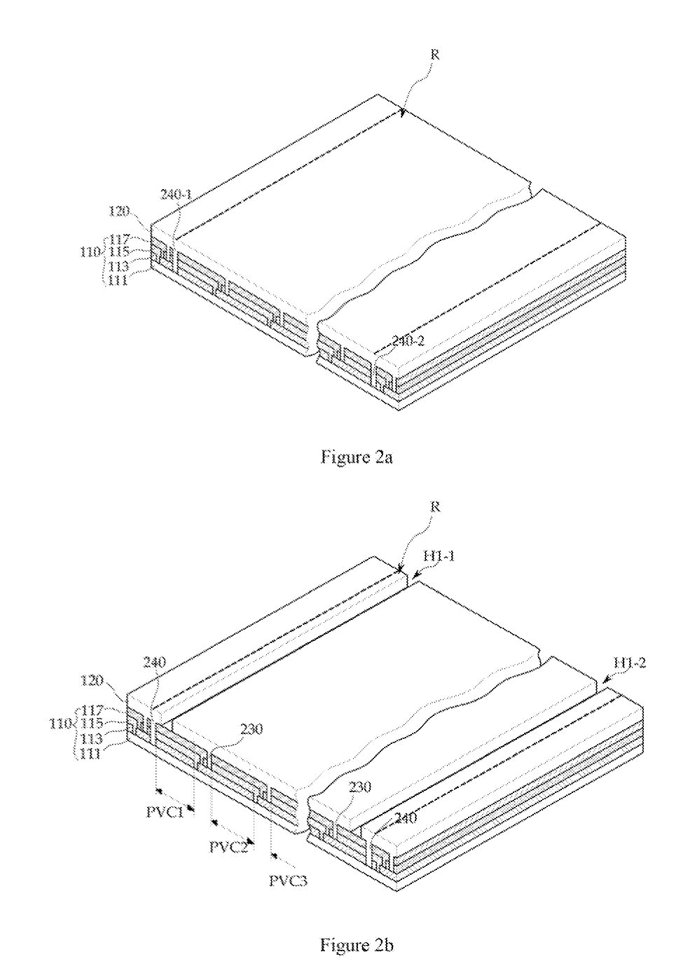

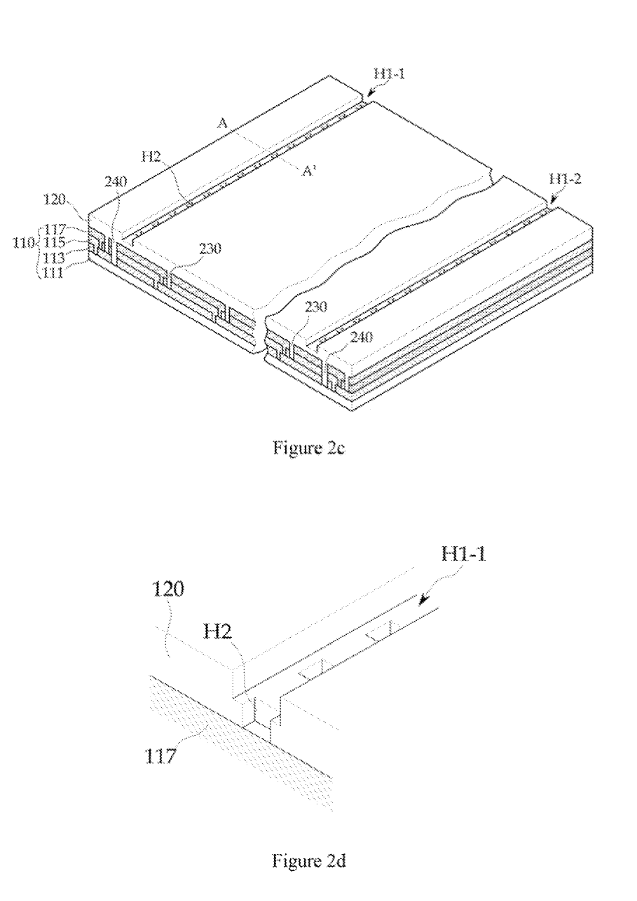

FIGS. 2a to 2d are views for describing a method for manufacturing an insulating layer 120 of a photovoltaic device according to the embodiment of the present invention. Though the following FIGS. 2a to 9g show that the photovoltaic substrate 110 and other layers are exposed to the outside as they are viewed from the side thereof, this is for convenience of description. It is noted that they are not exposed to the outside in a photovoltaic device actually manufactured.

As shown in FIG. 2a, fourth separation grooves 240-1 and 240-2 are formed on both sides of the provided photovoltaic substrate 110 respectively. The fourth separation grooves 240-1 and 240-2 are formed by scribing the second electrode 117, the photoelectric conversion layer 115 and the first electrode 113 by irradiating a laser beam in the air. The fourth grooves 240-1 and 240-2 determine an effective area “R” and an ineffective area on the photovoltaic substrate. A photo-electro motive force is generated in the effective area “R”. A photo-electro motive force is not generated in the ineffective area.

After the fourth separation grooves 240-1 and 240-2 are formed, an insulating layer 120 covering the second electrode 117, the third separation groove 230 and the fourth separation groove 240 is formed by a lamination process. The insulating layer 120 protects the photovoltaic substrate 110 and may include ethylene vinyl acetate (EVA).

As shown in FIG. 2b, two first and second trench lines H1-1 and H1-2 are formed in the insulating layer 120 such that the second electrode 117 is exposed. Here, it is desirable that the first and the second trench lines H1-1 and H1-2 are formed on the second electrode 117 on a portion of the effective area “R”, which is adjacent to the fourth separation grooves 240-1 and 240-2. Also, it is desirable that at least two photovoltaic cells PVC1, PVC2 and PVC3 are included between the first and the second trench lines H1-1 and H1-2. Since the fourth separation groove 240 is formed in the first photovoltaic cell PVC1, a photo-electro motive force is not generated in the first photovoltaic cell PVC1 and the first electrode and the second electrode of the first photovoltaic cell PVC1 are equipotential to each other. A photo-electro motive force is generated in the second photovoltaic cell PVC2 and the third photovoltaic cell PVC3 since the fourth separation groove 240 is not formed therein. Therefore, it is desirable to include at least two photovoltaic cells between the first and the second trench lines H1-1 and H1-2.

Here, the first and the second trench lines H1-1 and H1-2 exposing the second electrode 117 may be formed as shown in FIGS. 2c and 2d. Hereinafter, the first and the second trench lines H1-1 and H1-2 will be described in detail.

As shown in FIG. 2c, the first and the second trench lines H1-1 and H1-2 are formed in the insulating layer 120 such that the second electrode 117 is not exposed. That is, the first and the second trench lines H1-1 and H1-2 are formed to have a depth smaller than the thickness of the insulating layer 120. After the first and the second trench lines H1-1 and H1-2 are formed, a plurality of trenches H2 are formed on the bottom surfaces of the first and the second trench lines H1-1 and H1-2 such that the second electrode 117 is exposed. FIG. 2d is referred to so as to describe in detail a method for forming the trench H2.

FIG. 2d is an enlarged cross sectional view taken along line A-A′ of FIG. 2c. Referring to FIG. 2d, a laser beam is irradiated in the air and a plurality of the trenches H2 are formed and spaced apart from each other on the bottom surfaces of the first and the second trench lines H1-1 and H1-2. Here, a distance between the adjacent trenches H2 is desirable to be from 1.0 cm to 10 cm. When the spaced distance is less than 1.0 cm, it is difficult and takes a long time to form the trenches. When the spaced distance is greater than 10 cm, the number of contact points at which a conductive material filled in the trench H2 comes in contact with the second electrode 117 is reduced. This causes resistance increased and so heat generated.

Meanwhile, in description of FIGS. 2b and 2c, while the first and the second trench lines H1-1 and H1-2 and the trench H2 are formed after the insulating layer 120 is formed, a three-dimensional printing technology allows the first and the second trench lines H1-1 and H1-2 and the trench H2 as well as the insulating layer 120 to be formed at the same time.

Here, the three-dimensional printing technology corresponds to a technology of forming a three-dimensional structure by putting high polymer material of liquid state into a cartridge of a three-dimensional printer and by printing or spray the high polymer material layer by layer. Such a three-dimensional printing technology is recently used in the fields of an electronic industry and a biotechnology as well as a conventional simple paper printing. Through the three-dimensional printing technology, there are advantages in that the production on a large scale and the reduction in the manufacturing time are allowed.

A method for forming the insulating layer 120 by using the three-dimensional printing technology is as follows. Curable high polymer in liquid state, i.e., a constituent material of the insulating layer 120 is put into the cartridge of the three-dimensional printer and is sprayed on the photovoltaic substrate 110. At this time, the insulating layer 120 is formed in a three-dimensional manner such that the first and the second trench lines H1-1 and H1-2 and a plurality of the trenches H2 are formed.

Hereinafter, photovoltaic devices of the present invention will be described on the basis of the photovoltaic device shown in FIG. 2c for the sake of convenience of description. Therefore, embodiments of the present invention to be described below may be based on the insulating layer 120 shown in FIG. 2b.

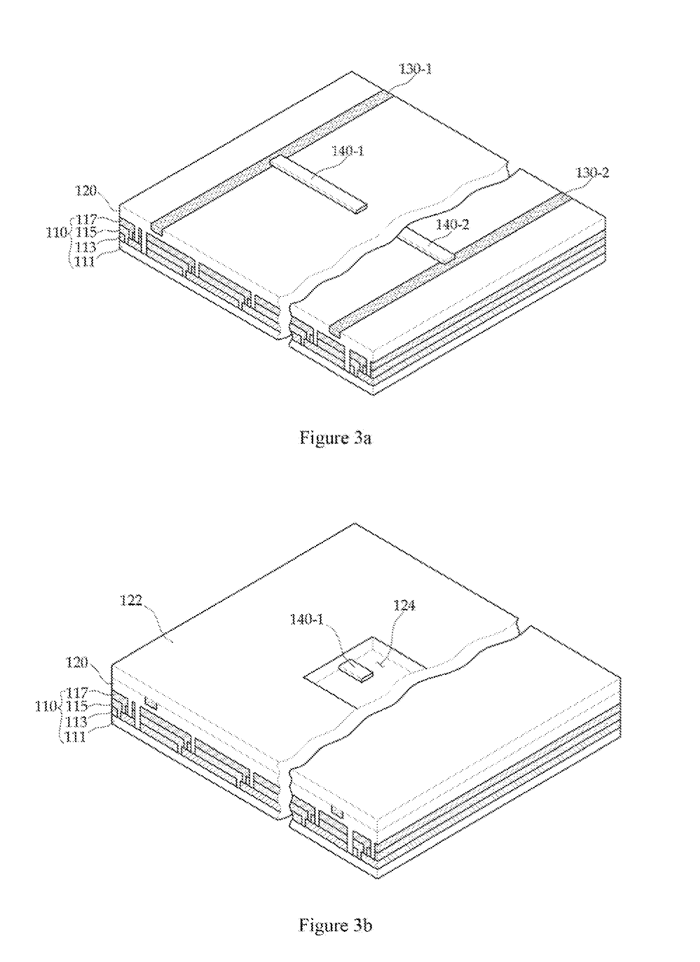

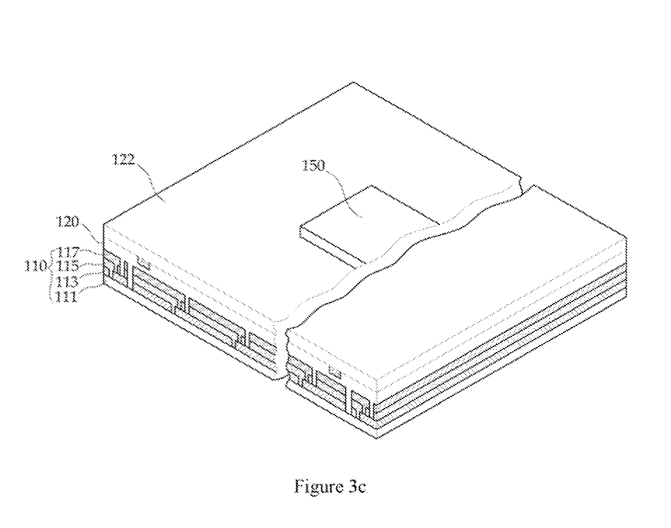

FIGS. 3a to 3b are views for describing a photovoltaic device and a method for manufacturing the photovoltaic device according to a first embodiment of the present invention. Referring to FIG. 3a, a conductive material is filled in the first and the second trench lines H1-1 and H1-2 and a plurality of the trenches H2 which have been formed in the insulating layer 120, so that a first conductive bus bar 130-1 and a second conductive bus bar 130-2 are formed. Therefore, the second electrode 117 comes in contact with and is electrically connected to the first and the second conductive bus bars 130-1 and 130-2.

Here, it is desirable that the first and the second conductive bus bars 130-1 and 130-2 have a vertical cross sectional area from 0.3 mm² to 1.0 mm². When the area is smaller than 0.3 mm², heat is generated due to a resistance increase so that efficiency and a life span of a photovoltaic device are reduced. When greater than 1.0 mm², the amount of the conductive material used is increased, so that the manufacturing cost is increased.

After the first and the second conductive bus bars 130-1 and 130-2 are formed, a first conductive wire 140-1 and a second conductive wire 140-2 are formed in order to electrically connect the first and the second conductive bus bars 130-1 and 130-2 with a junction box 150. One side of the first conductive wire 140-1 comes in contact with the first conductive bus bar 130-1, and the other side of the first conductive wire 140-1 is formed on the insulating layer 120. One side of the second conductive wire 140-2 comes in contact with the second conductive bus bar 130-2, and the other side of the second conductive wire 140-2 is formed on the insulating layer 120. Here, the other side of the first conductive wire 140-1 is apart from and not connected to the other side of the second conductive wire 140-2. The first conductive wire 140-1 and the second conductive wire 140-2 are formed by printing conductive metallic paint including Ag, Au, Cu or Al or by printing conductive paint including ZnO, CNT or graphene, and then by performing a drying process or a curing process.

Here, it is desirable that the first and the second conductive wires 140-1 and 140-2 have a vertical cross sectional area from 0.3 mm² to 1.0 mm². When the area is smaller than 0.3 mm², heat is generated due to a resistance increase so that efficiency and a life span of a photovoltaic device are reduced. When greater than 1.0 mm², the amount of the conductive material used is increased, so that the manufacturing cost is increased.

Referring to FIG. 3b, after the first and the second conductive wires 140-1 and 140-2 are formed, a cover layer 122 is formed. Here, a junction hole 124 into which the junction box is inserted is formed in the cover layer 122. The other sides of the first and the second conductive wires 140-1 and 140-2 are exposed through the junction hole 124. Therefore, when the junction box is inserted later into the junction hole 124, two terminals of the junction box are electrically connected to the first and the second conductive wires 140-1 and 140-2 respectively.

The junction hole 124 can be formed by using a mask at the time of forming the cover layer 122. As described above, the cover layer 122 having the junction hole 124 can be formed by using the three-dimensional printing technology used for forming the insulating layer 120. It is desirable to use the three-dimensional printing technology for the purpose of production on a large scale and reduction of manufacturing time. The cover layer 122 prevents the first and the second conductive bus bars 130-1 and 130-2 and the first and the second conductive wires 140-1 and 140-2 from being corroded by air or moisture.

It is desirable that the insulating layer 120 and the cover layer 122 have a thickness from 0.3 mm to 5 mm. When the thickness is less than 0.3 mm, it is difficult to prevent the first and the second conductive bus bars and the first and the second conductive wires from being corroded and durability is deteriorated. When larger than 5 mm, the amount of an insulating material constituting the insulating layer 120 and the cover layer 122 is increased, so that the manufacturing cost increases.

Referring to FIG. 3c, the junction box 150 is inserted into the junction hole 124 formed in the cover layer 122. Meanwhile, the junction box 150 shown in FIG. 3c is a 2-terminal type junction box. This is an example of the junction box. The junction box 150 may be a 1-terminal type junction box.

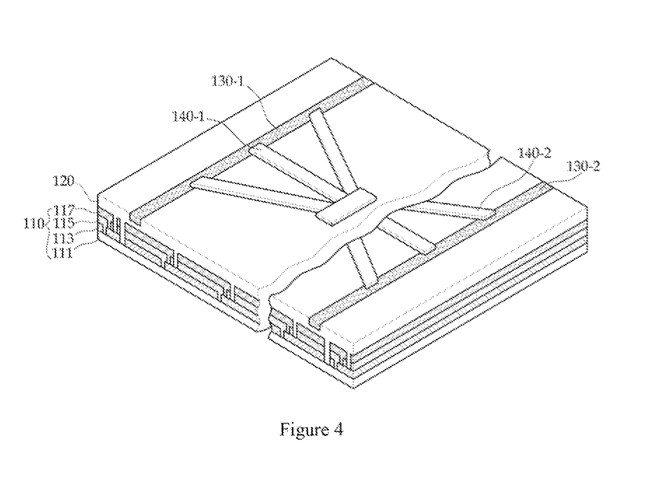

FIG. 4 is a view for describing a photovoltaic device and a method for manufacturing the photovoltaic device according to a second embodiment of the present invention. Referring to FIG. 4, a photovoltaic device according to a second embodiment of the present invention includes a plurality of the first and the second conductive wires 140-1 and 140-2 of the photovoltaic device according to the first embodiment shown in FIGS. 3a to 3c. A plurality of the first conductive wires 140-1 and a plurality of the second conductive wires 140-2 are connected in parallel to each other. When a plurality of the first conductive wires 140-1 are connected in parallel to each other, a total resistance of the first conductive wires 140-1 becomes less than that of when one conductive wire 140-1 is used. Therefore, heat generation is reduced as compared with when one conductive wire is used. As a result, efficiency and long term durability of a photovoltaic module are improved.

As such, the photovoltaic device according to the second embodiment of the present invention can be obtained by performing the process shown in FIGS. 3b to 3c after forming a plurality of the conductive wires.

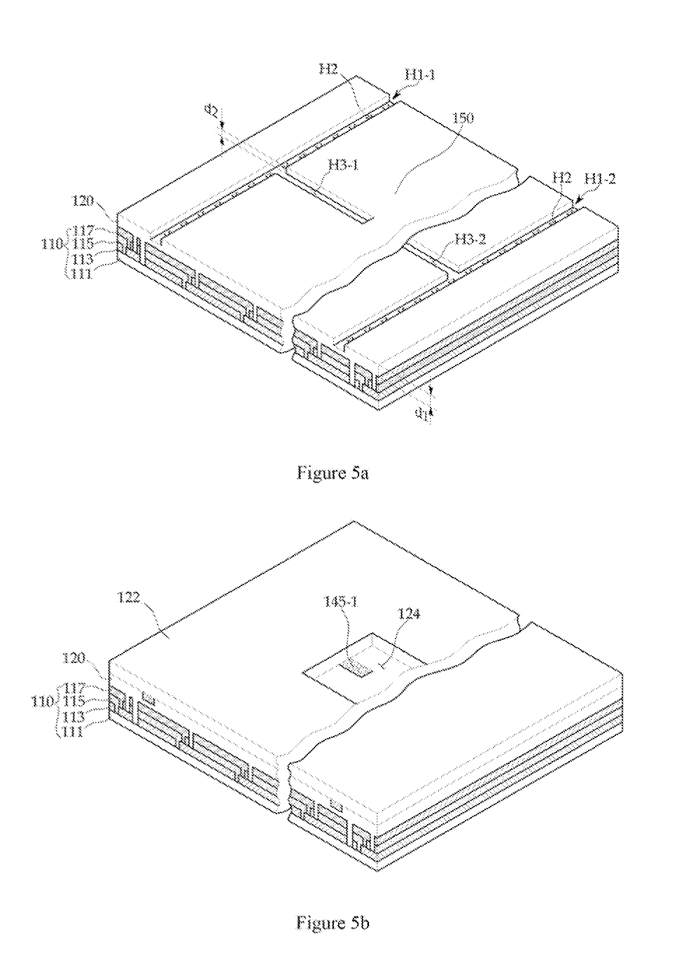

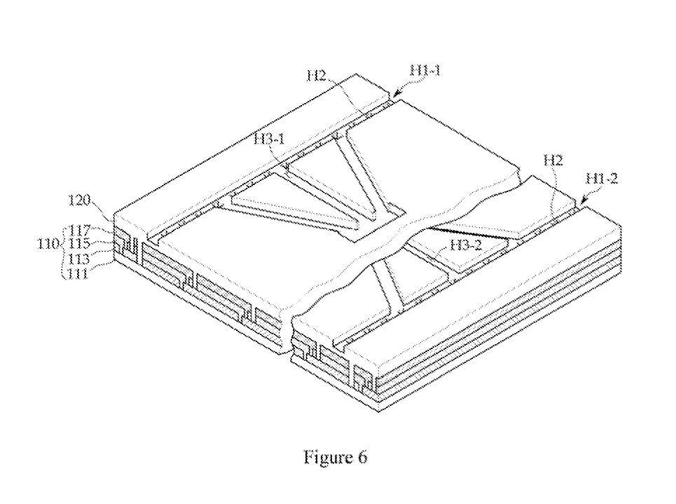

FIGS. 5a to 5b are views for describing a photovoltaic device and a method for manufacturing the photovoltaic device according to a third embodiment of the present invention.

Referring to FIG. 5a, in a photovoltaic device according to a third embodiment of the present invention, the first and the second trench lines H1-1 and H1-2 and a plurality of the trenches H2 are formed in the insulating layer 120, and then a first extended trench line H3-1 and a second extended trench line H3-2 are formed.

Here, one side of the first extended trench line H3-1 is connected to the first trench line H1-1, and the other side of the first extended trench line H3-1 is formed in the insulating layer 122. One side of the second extended trench line H3-2 is connected to the second trench line H1-2, and the other side of the second extended trench line H3-2 is formed in the insulating layer 122. Here, the other side of the first extended trench line H3-1 is apart from and not connected to the other side of the second extended trench line H3-2.

Depth “d2” of the first and the second extended trench lines H3-1 and H3-2 may be the same with or different from that of the first and the second trench lines H1-1 and H1-2. However, it is desirable that the depth “d2” of the first and the second extended trench lines H3-1 and H3-2 is smaller than the thickness “d1” of the insulating layer 120.

Referring to FIG. 5b, after the first and the second extended trench lines H3-1 and H3-2 are formed, a conductive wire 145-1 is formed by filling a conductive material into the first and the second trench lines H1-1 and H1-2, trenches H2 and the first and the second extended trench lines H3-1 and H3-2.

Subsequently, the cover layer 122 is formed on the insulating layer 120. Then, the junction hole 124 into which the junction box is inserted is formed in the cover layer 122. The other sides of the first and the second extended trench lines are exposed through the junction hole 124. The junction hole 124 is formed by a two-dimensional printing method using a mask. As described above, the cover layer 122 having the junction hole 124 may be formed by using a three-dimensional printing technology. Next, the junction box is inserted into the junction hole 124. Since the insertion of the junction box has been described in FIG. 3c, descriptions thereof will be omitted.

FIG. 6 is a view for describing a photovoltaic device and a method for manufacturing the photovoltaic device according to a fourth embodiment of the present invention.

Referring to FIG. 6, a photovoltaic device according to a fourth embodiment of the present invention includes a plurality of the first and the second connection trench lines H3-1 and H3-2 of the photovoltaic device according to the third embodiment shown in FIGS. 5a to 5b. Through the formation of a plurality of the first connection trench lines H3-1 and a plurality of the second connection trench lines H3-2, it is possible to obtain the same or similar effect described in FIG. 4.

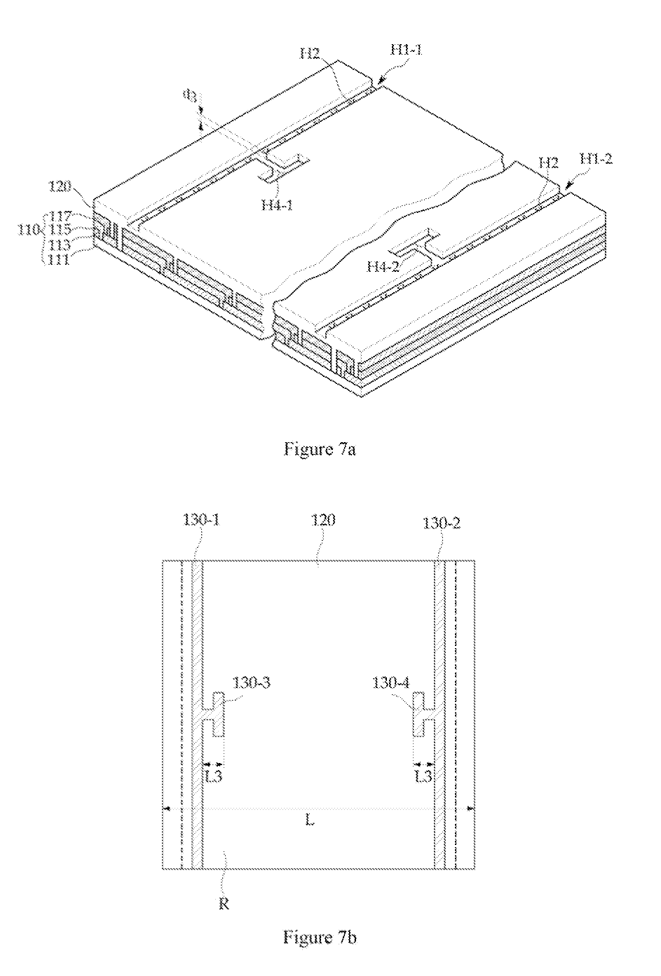

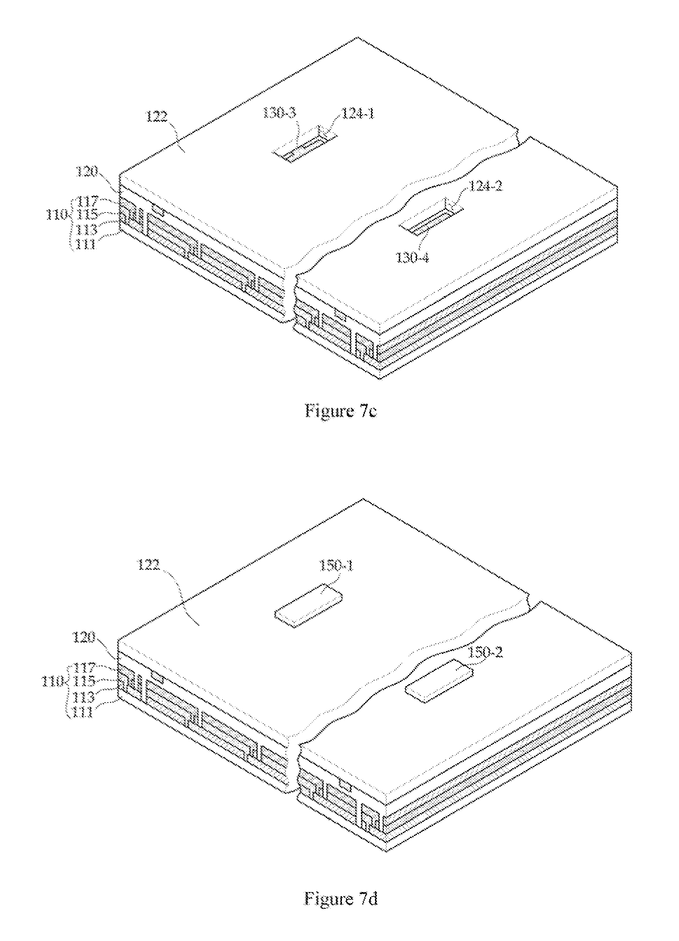

FIGS. 7a to 7d are views for describing a photovoltaic device and a method for manufacturing the photovoltaic device according to a fifth embodiment of the present invention.

As shown in FIGS. 7a to 7b, a first pad trench H4-1 and a second pad trench H4-2 are formed in the insulating layer 120 before the first and the second trench lines H1-1 and H1-2 and the trenches H2 are filled with a conductive material. Here, it is desirable that the first and the second pad trenches H4-1 and H4-2 are formed in the effective area “R” of the photovoltaic substrate 110.

The first and the second pad trenches H4-1 and H4-2 shown in FIGS. 7a to 7b have a T-shape. One sides of the first and the second pad trenches H4-1 and H4-2 are connected to the first and the second trench lines H1-1 and H1-2. Here, it is not necessary for the first and the second pad trenches H4-1 and H4-2 to have a T-shape. The first and the second pad trenches H4-1 and H4-2 can have any shape of a connection pattern for electrically connecting themselves with cables of a junction box of another photovoltaic device.

Depth “d3” of the first and the second pad trenches H4-1 and H4-2 may be the same with or different from that of the first and the second trench lines H1-1 and H1-2. However, it is desirable that the depth “d3” of the first and the second pad trenches H4-1 and H4-2 is smaller than the thickness of the insulating layer 120. There is a predetermined distance “L3” between the first and the second pad trenches H4-1 and H4-2 and the first and the second trench lines H1-1 and H1-2. Here, it is desirable that the predetermined distance “L3” is equal to or less than a third of a shorter side length L of the photovoltaic substrate 110. In this case, it is possible to reduce installation cost by effectively reducing the length of an electric wire when forming a solar array.

The first and the second conductive bus bars 130-1, 130-2, 130-3 and 130-4 are formed by filling a conductive material into the first and the second trench lines H1-1 and H1-2, the trench H2 and the first and the second pad trenches H4-1 and H4-2.

Referring to FIG. 7c, a cover layer 122 is formed on the insulating layer 120 and the first and the second conductive bus bars 130-1, 130-2, 130-3 and 130-4. Junction holes 124-1 and 124-2 are formed at the time of forming the cover layer 122. The junction hole 124-1 and 124-2 exposes the first and the second conductive bus bars 130-3 and 130-4 filled in the first and the second pad trenches H4-1 and H4-2.

Referring to FIG. 7d, junction boxes 150-1 and 150-2 are installed through the junction holes 124-1 and 124-2, so that the first and the second conductive bus bars 130-1, 130-2, 130-3 and 130-4 are electrically connected to the junction boxes 150-1 and 150-2.

As shown in FIGS. 7a to 7d, the bus bars 130-3 and 130-4 formed by filling a conductive material into the first and the second pad trenches H4-1 and H4-2 are connected to an adjacent photovoltaic device through the junction box and cables, so that a plurality of the photovoltaic devices shown in FIG. 7d can be connected to each other.

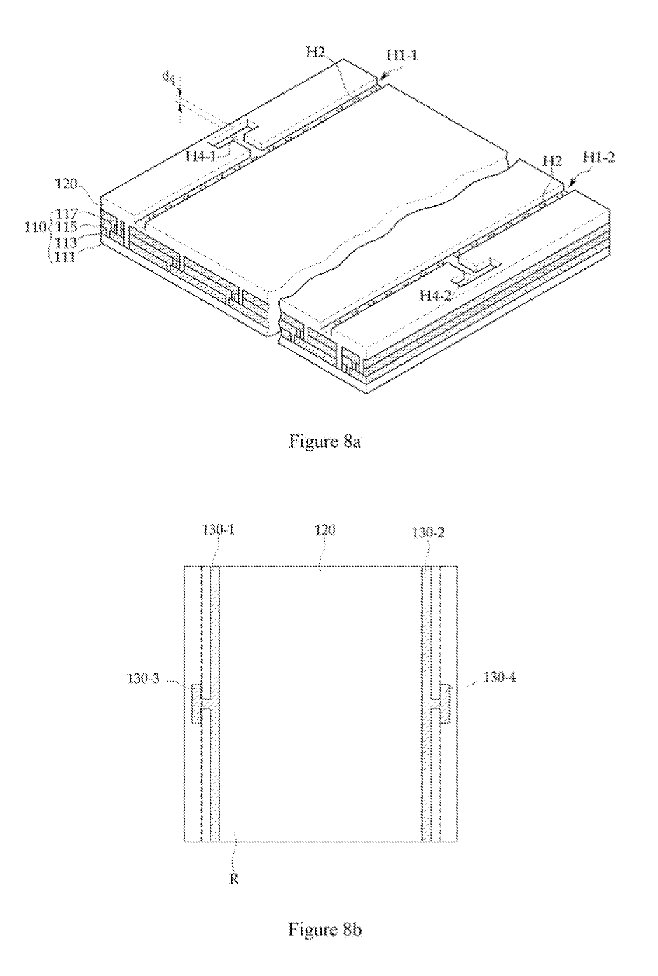

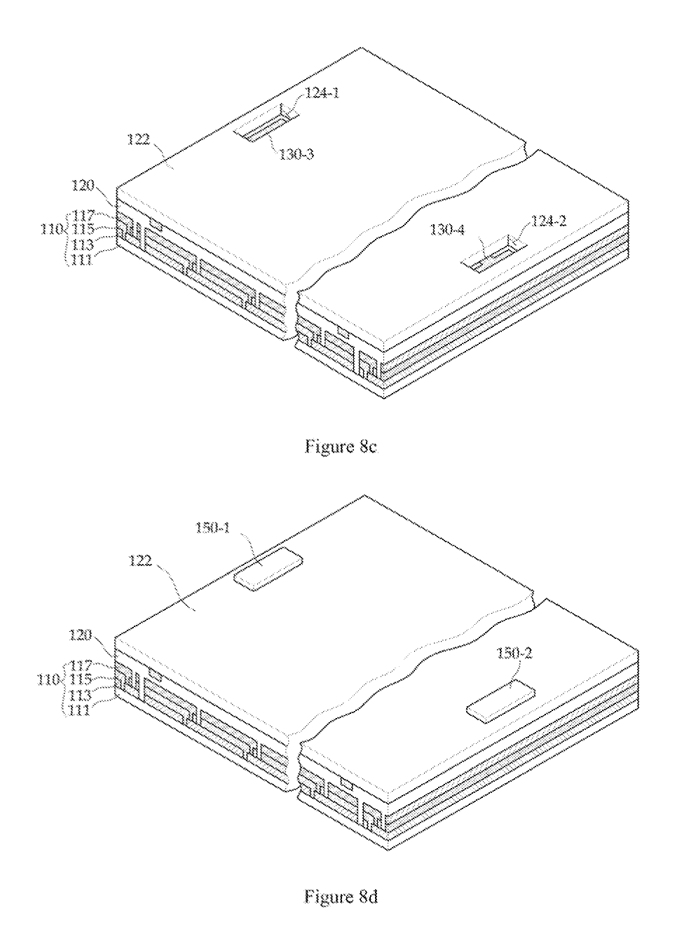

FIGS. 8a to 8d are views for describing a photovoltaic device and a method for manufacturing the photovoltaic device according to a sixth embodiment of the present invention.

As shown in FIGS. 8a to 8b, before the first and the second trench lines H1-1 and H1-2 and the trench H2 are filled with a conductive material, the first and the second pad trenches H4-1 and H4-2 are formed in the insulating layer 120. Here, the first and the second pad trenches H4-1 and H4-2 are formed in the ineffective area, unlike the photovoltaic device shown in FIGS. 7a to 7b.

The formed first and second pad trenches H4-1 and H4-2 have a T-shape. One sides of the first and the second pad trenches H4-1 and H4-2 are connected to the first and the second trench lines H1-1 and H1-2. Here, it is not necessary for the first and the second pad trenches H4-1 and H4-2 to have a T-shape. The first and the second pad trenches H4-1 and H4-2 can have any shape of a connection pattern for electrically connecting themselves with cables of a junction box of another photovoltaic device.

Depth “d4” of the first and the second pad trenches H4-1 and H4-2 may be the same with or different from that of the first and the second trench lines H1-1 and H1-2. However, it is desirable that the depth “d4” of the first and the second pad trenches H4-1 and H4-2 is smaller than the thickness of the insulating layer 120.

A conductive material is filled in the first and the second trench lines H1-1 and H1-2, the trenches H2 and the first and the second pad trenches H4-1 and H4-2, so that a first conductive bus bar 130-1 and a second conductive bus bar 130-2 are formed.

Referring to FIG. 8c, a cover layer 122 is formed on the insulating layer 120 and the first and the second conductive bus bars 130-1, 130-2, 130-3 and 130-4. Junction holes 124-1 and 124-2 are formed at the time of forming the cover layer 122. The junction holes 124-1 and 124-2 expose the first and the second conductive bus bars 130-3 and 130-4 filled in the first and the second pad trenches H4-1 and H4-2.

Referring to FIG. 8d, junction boxes 150-1 and 150-2 are installed through the junction holes 124-1 and 124-2, so that the first and the second conductive bus bars 130-1, 130-2, 130-3 and 130-4 are electrically connected to the junction boxes 150-1 and 150-2.

As shown in FIGS. 8a to 8d, the bus bars 130-3 and 130-4 formed by filling a conductive material into the first and the second pad trenches 1-14 are connected to an adjacent photovoltaic device through the junction box and cables, so that a plurality of the photovoltaic devices shown in FIG. 8d can be connected to each other.

Through the use of the photovoltaic devices according to the fifth and the sixth embodiments of the present invention shown in FIGS. 7a to 7d and FIGS. 8a to 8d, a plurality of the photovoltaic devices can be easily connected in series or in parallel to each other.

More specifically, after the bus bars 130-3 and 130-4 are formed by filling a conductive material into the first and the second pad trenches H4-1 and H4-2 according to the fifth or the sixth embodiment, a junction box with one terminal and one cable is connected to the bus bars 130-3 and 130-4, and then the cable is connected to the junction box of an adjacent photovoltaic device. As a result, it is possible to reduce installation cost by effectively reducing the length of an electric wire when forming a solar array.

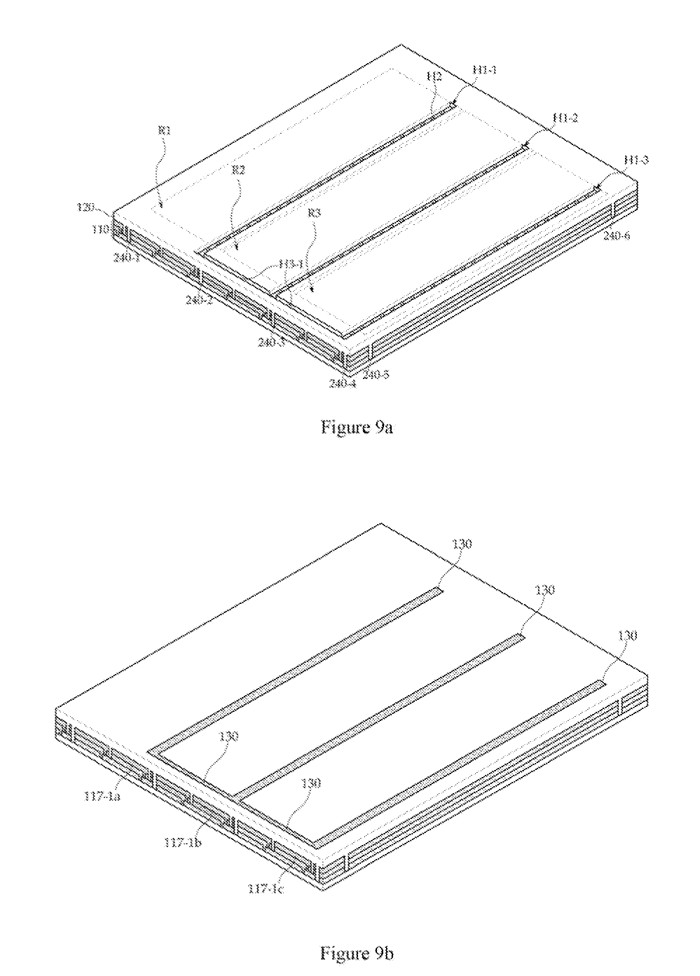

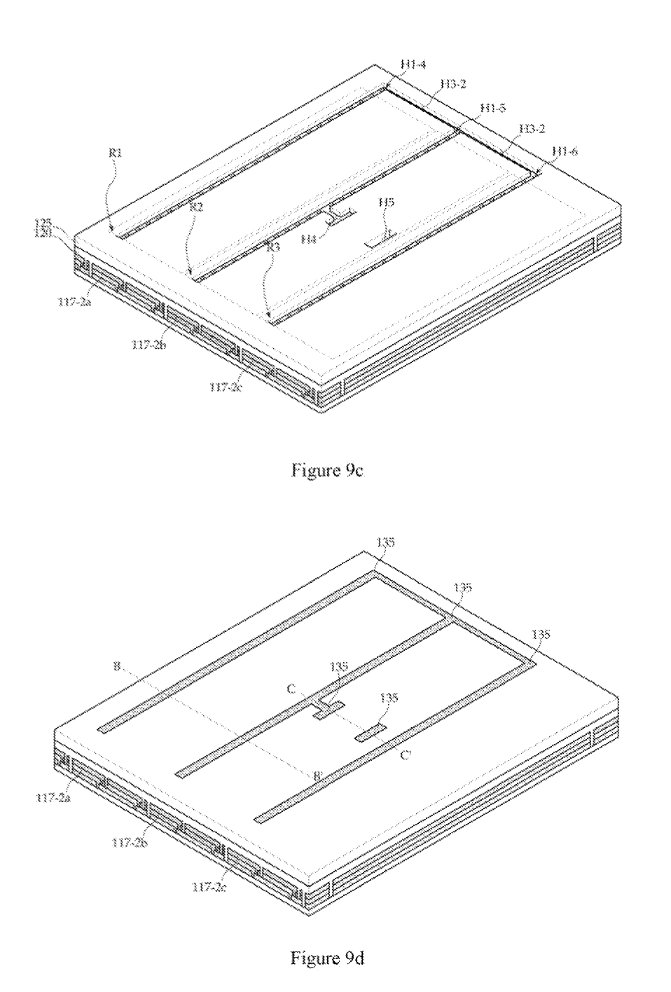

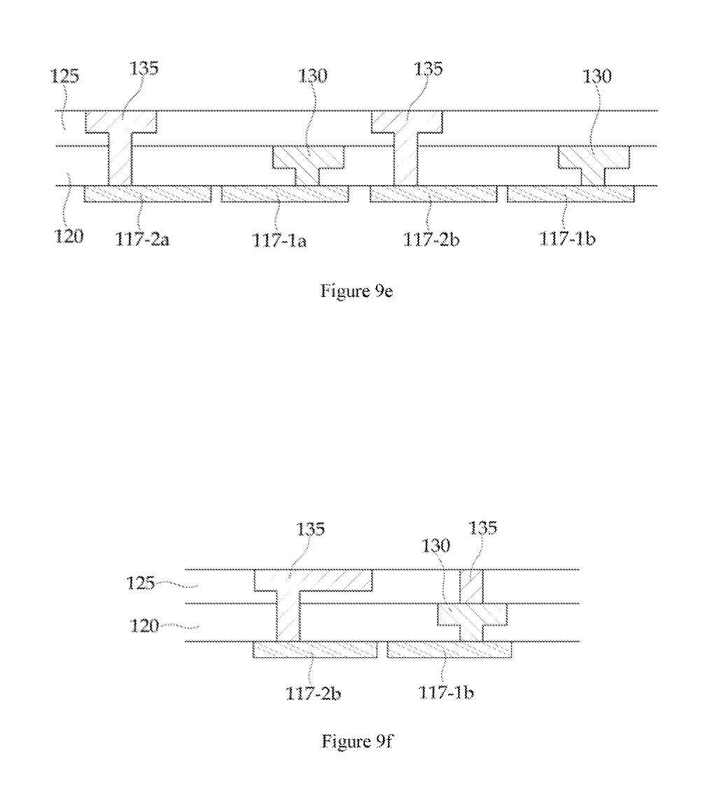

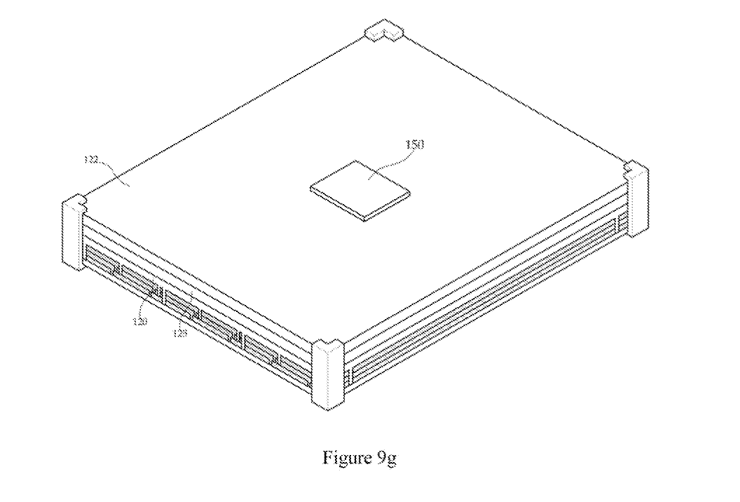

FIGS. 9a to 9g are views for describing a photovoltaic device and a method for manufacturing the photovoltaic device according to a seventh embodiment of the present invention. Referring to FIG. 9a, a photovoltaic substrate 110 is provided by using the same manufacturing method as that of FIGS. 1a to 1e. A plurality of fourth separation grooves 240-1, 240-2, 240-3 and 240-4 are formed to be spaced apart from each other at a regular interval in a horizontal direction of the photovoltaic substrate 110. Also; two fourth separation grooves 240-5 and 240-6 are formed on both sides of the photovoltaic substrate 110 in a longitudinal direction of the photovoltaic substrate 110. The formed six fourth separation grooves 240-1, 240-2, 240-3, 240-4, 240-5 and 240-6 divide the photovoltaic substrate 110 into three effective areas R1, R2 and R3 and the rest of ineffective area.

Next, a first insulating layer 120 is formed on the photovoltaic substrate 110, and then a first, a second and a third trench'lines H1-1, H1-2 and H1-3 are formed in the first insulating layer 120. The first to the third trench lines H1-1, H1-2 and H1-3 are allocated to the three effective areas R1, R2 and R3 respectively.

Then, a plurality of trenches H2 are formed in the first to the third trench lines H1-1, H1-2 and H1-3. A first connection trench line H3-1 connecting the first to the third trench lines H1-1, H1-2 and H1-3 with each other is formed in the first insulating layer 120 on the ineffective area. Here, it is noted that the first insulating layer 120 having the first to the third trench lines H1-1, H1-2 and H1-3 and the first connection trench line H3-1 can be formed by using three-dimensional printing technology. Moreover, the first connection trench line H3-1 may be formed over the three effective areas R1, R2 and R3 other than in the ineffective area. The figure shows the first connection trench line H3-1 formed in the ineffective area since the ineffective area is an unnecessary portion of the photovoltaic device.

Referring to FIG. 9b, a first conductive bus bar 130 is formed by filling a conductive material into the first to the third trench lines H1-1, H1-2 and H1-3, a plurality of the trenches H2 and the first connection trench line H3-1. Therefore, the first conductive bus bar 130 is electrically connected to three second electrodes 117-1a, 117-1b and 117-1c to be negative electrodes. The three second electrodes 117-1a, 117-1b and 117-1c are connected in parallel.

Referring to FIG. 9c, a second insulating layer 125 is formed on the first insulating layer 120. After the second insulating layer 125 is formed, a fourth, a fifth and a sixth trench lines H1-4, H1-5 and H1-6 are formed in the second insulating layer 125. Here, the fourth to the sixth trench lines H1-4, H1-5 and H1-6 are allocated to the three effective areas R1, R2 and R3 respectively. The fourth to the sixth trench lines H1-4, H1-5 and H1-6 should not be formed over the first conductive bus bar 130 formed in the first insulating layer 120.

Then, a plurality of the trenches H2 are formed in the fourth to the sixth trench lines H1-4, H1-5 and H1-6. Here, a plurality of the trenches H2 penetrate the second insulating layer 125 and the first insulating layer 120, so that the second electrodes 117-2a, 117-2b and 117-2c are exposed.

A second connection trench line H3-2 connecting the fourth to the sixth trench lines H1-4, H1-5 and H1-6 with each other is formed in the second insulating layer 125 on the ineffective area. Here, it is noted that the second connection trench line H3-2 can be formed in the effective area other than in the ineffective area.

In the next step, a first pad trench H4 and a second pad trench H5 are formed in the second insulating layer 125. The first pad trench H4 has a T-shape in the figure. However, the first pad trench H4 can have various shapes without being limited to this. Though the second pad trench H5 has a straight line shape, the second pad trench H5 can also have various shapes without being limited to this.

The first pad trench H4 may be formed in the ineffective area of the photovoltaic substrate 110. For example, the first pad trench H4 is connected to one side of the fourth trench line H1-4, so that the first pad trench H4 is formed in the ineffective area. The second pad trench H5 may be also formed in the ineffective area of the photovoltaic substrate 110. For example, the second pad trench H5 may be formed over the first connection trench line H3-1 formed in the ineffective area. In the case where the first pad trench H4 and the second pad trench H5 are formed in the ineffective area, a 2-terminal type junction box or two 1-terminal type junction boxes can be employed in accordance with a distance between two connection pads 135. One side of the T-shaped first pad trench H4 is connected to the fifth trench line H1-5 formed in the second insulating layer 125.

The second pad trench H5 is formed over the first conductive bus bar 130 in the first insulating layer 120 and penetrates the second insulating layer 125. Therefore, a portion of the first conductive bus bar 130 is exposed by the second pad trench H5. Here, it should be noted that the second pad trench H5 is not connected to the fourth to the sixth trench lines H1-4, H1-5 and H1-6 formed in the second insulating layer 125.

Referring to FIG. 9d, a second conductive bus bar 135 is formed by filling a conductive material into the fourth to the sixth trench lines H1-4, H1-5 and H1-6, a plurality of the trenches H2, the second connection trench line H3-2, the first pad trench H4 and the second pad trench H5, which are formed in the second insulating layer 125. Therefore, the second conductive bus bar 135 is electrically connected to three second electrodes 117-2a, 117-2b and 117-2c to be positive electrodes.

The conductive material filled in the straight line-shaped second pad trench H5 is electrically connected to the first conductive bus bar 130. Detailed description thereof will be provided with reference to FIGS. 9e to 9f.

FIG. 9e is a cross sectional view taken along the line B-B′ of FIG. 9d. FIG. 9f is a cross sectional view taken along the line C-C′ of FIG. 9d.

Referring to FIG. 9e, the first conductive bus bar 130 formed in the first insulating layer 120 is electrically connected to the second electrodes 117-1a and 117-1b. The second conductive bus bar 135 formed in the second insulating layer 125 is electrically connected to the second electrodes 117-2a and 117-2b.

Referring to FIG. 9f, the first conductive bus bar 130 formed in the first insulating layer 120 is electrically connected to the second electrode 117-1b. The conductive material filled in the straight line-shaped second pad trench H5 formed in the second insulating layer 125 is electrically connected to the first conductive bus bar 130. The conductive material filled in the T-shaped first pad trench H4 in the second insulating layer 125 is electrically connected to the second electrode 117-2b.

Referring to FIG. 9g, a cover layer 122 and a junction box 150 are formed on the second insulating layer 125, after the second conductive bus bar 135 is formed. The explanation for forming the cover layer 122 and the junction box 150 will be replaced with the description of FIGS. 3b and 3c.

In the photovoltaic device according to the seventh embodiment of the present invention shown in FIG. 9g, the positive electrode of the 2-terminal type junction box 150 is electrically connected to the conductive material filled in the first pad trench H4. The negative electrode of the 2-terminal type junction box 150 is electrically connected to the conductive material filled in the second pad trench H5. Therefore, since the conductive material filled in the second pad trench H5 is electrically connected to the first conductive bus bar 130, the negative electrode of the junction box 150 is electrically connected to the first conductive bus bar 130.

As a result, the positive electrode of the junction box 150 is electrically connected to the second conductive bus bar 135 formed in the second insulating layer 125. The negative electrode of the junction box 150 is electrically connected to the first conductive bus bar 130 formed in the first insulating layer 120.

In the seventh embodiment of the present invention, the photovoltaic device formed in accordance with the manufacturing method shown in FIGS. 9a to 9g includes the photovoltaic substrate 110 which is divided into three effective areas R1, R2 and R3 and the ineffective area.

Each of the three effective areas R1, R2 and R3 includes the one first conductive bus bar 130 and the one second conductive bus bar 135. Here, the three first conductive bus bars 130 are formed in the first insulating layer 120 and are electrically connected to the negative electrode of the junction box 150. The three second conductive bus bars 135 are formed in the second insulating layer 125 and are electrically connected to the positive electrode of the junction box 150.

In the ineffective area of the photovoltaic substrate 110, the three first conductive bus bars 130 are connected in parallel in the first insulating layer 120 on the ineffective area. The three second conductive bus bars 135 are connected in parallel in the second insulating layer 125 on the ineffective area.

The negative electrode of the junction box 150 is electrically connected to the first conductive bus bars 130 by the straight line-shaped second pad trench H5 formed in the first and the second insulating layers 120 and 125.

The photovoltaic device according to the seventh embodiment of the present invention can obtain three photovoltaic devices connected in parallel to each other by using one photovoltaic substrate. Accordingly, the number of the photovoltaic modules which can be connected to an inverter is increased by lowering the open circuit voltage of the photovoltaic device, so that the number of the inverters of a solar power plant may be reduced and installation cost thereof may also be reduced. In other words, in the past, since many photovoltaic substrates are connected in series, the number of the photovoltaic modules which can be connected in series to the inverter is small, so that many inverters are required. However, through the use of a plurality of the photovoltaic devices according to the seventh embodiment of the present invention, the solar array includes photovoltaic devices connected in series and in parallel, so that the open circuit voltage of the solar array is lower than that of the conventional solar array including photovoltaic devices connected in series only. As a result, the load to the inverter can be reduced.

In addition, referring to FIG. 9g, a photovoltaic device according to the eighth embodiment of the present invention is formed by forming a protector 160 at the corners of the photovoltaic substrate 110 on which the insulating layer 120 is formed, the insulating layer 120, the second insulating layer 125 and the cover layer 122 of the photovoltaic device according to the seventh embodiment.

The protector 160 protects the photovoltaic device. It is desirable that the protector 160 is formed of a plastic material having rigidity for preventing the corners of the photovoltaic device from being destroyed. The protector 160 prevents the first insulating layer 120 and the second insulating layer 125 in the lateral side of the photovoltaic device from being exfoliated and prevents water from permeating the photovoltaic device.

Here, the protector 160 can be added to the photovoltaic devices according to the first to the sixth embodiments of the present invention.

Up to now, the exemplary embodiments of the present invention have been described. It can be understood by those skilled in the art that many alternatives, modifications, and variations of the present invention can be made without departing from the essential features of the present invention. Therefore, the disclosed embodiments are merely exemplary and are not to be construed as limiting the present invention. The scope of the present invention is shown in the appended claims and not in the foregoing descriptions. It should be construed that all differences within the scope equivalent to that of the claims are included in the present invention.

What is claimed is:

1. A method for manufacturing a photovoltaic device, the method comprising:
forming sequentially a first electrode, a photoelectric conversion layer and a second electrode on a substrate;
forming an insulating layer covering the second electrode;
forming a first trench line and a second trench line in the insulating layer on the second electrode such that the second electrode is exposed, wherein at least two photovoltaic cells are included between the first trench line and the second trench line; and
forming a first conductive bus bar and a second conductive bus bar by filling the first and the second trench lines with a conductive material.

2. The method of claim 1, wherein the forming the first and the second trench lines comprises:
forming the first and the second trench lines in the insulating layer such that the second electrode is not exposed; and
forming a plurality of trenches on the bottom surfaces of the first and the second trench lines such that the second electrode is exposed.

3. The method of claim 2, wherein a distance between two adjacent trenches among a plurality of the trenches is equal to or more than 1.0 cm and equal to or less than 10 cm.

4. The method of claim 1, further comprising:
forming, after the first and the second conductive bus bars are formed, a first conductive wire and a second conductive wire on the insulating layer, wherein one side of the first conductive wire comes in contact with the first conductive bus bar, and wherein one side of the second conductive wire conies in contact with the second conductive bus bar;
forming a cover layer on the insulating layer, the first and the second conductive bus bars and the first and the second conductive wires, wherein a junction hole is formed such that the other sides of the first and the second conductive wires are exposed; and
electrically connecting the junction box with the first and the second conductive bus bars through the junction hole.

5. The method of claim 4, wherein a plurality of the first conductive wires and a plurality of the second conductive wires are formed respectively.

6. The method of claim 1, wherein the forming the first and the second trench lines further comprises:
forming a first extended trench line in the insulating layer, wherein one side of the first extended trench line is connected to the first trench line, and wherein the depth of the first extended trench line is smaller than the thickness of the insulating layer, and forming a second extended trench line in the insulating layer, wherein one side of the second extended trench line is connected to the second trench line, and wherein the depth of the second extended trench line is smaller than the thickness of the insulating layer,
forming a cover layer on the insulating layer and the first and the second conductive bus bars, wherein a junction hole is formed such that the other sides of the first and the second extended trench lines filled with the conductive material; and
electrically connecting a junction box with the first and the second conductive bus bars through the junction hole.

7. The method of claim 6, wherein a plurality of the first extended trench lines and a plurality of the second extended trench lines are formed respectively.

8. The method of claim 1, wherein the forming the first and the second trench lines further comprises:
forming a first pad trench in the insulating layer, wherein one side of the first pad trench is connected to the first trench line, and wherein the depth of the first pad trench is smaller than the thickness of the insulating layer, and forming a second pad trench in the insulating layer, wherein one side of the second pad trench is connected to the second trench line, and wherein the depth of the second pad trench is smaller than the thickness of the insulating layer,
forming a cover layer on the insulating layer and the first and the second conductive bus bars, wherein a junction hole is formed such that the first and the second pad trenches filled with the conductive material; and
electrically connecting a junction box with the first and the second conductive bus bars through the junction hole.

9. A method for manufacturing a photovoltaic device, the method comprising:
forming sequentially a first electrode, a photoelectric conversion layer and a second electrode on a substrate;
forming at least two effective areas and the rest of ineffective area in the first electrode, the photovoltaic conversion layer and the second electrode, wherein at least two photovoltaic cells are included in each of the effective areas;
forming a first insulating layer covering the second electrode;
forming a first trench line in the first insulating layer on the second electrode in each of the effective areas such that the second electrode is exposed, and forming a first connection trench line in the first insulating layer, wherein the first connection trench line connects a plurality of the first trench lines with each other;
forming a first conductive bus bar by filling a conductive material into a plurality of the first trench lines and the first connection trench line, which are formed in the first insulating layer;
forming a second insulating layer covering the first insulating layer and the first conductive bus bar;
forming a second trench line in the first and second insulating layers in each of the effective areas such that the second electrode is exposed, and forming a second connection trench line in the second insulating layer, wherein the second connection trench line connects a plurality of the second trench lines with each other;
forming a first pad trench in the second insulating layer such that one side of the first pad trench is connected to any one of a plurality of the second trench lines, and forming a second pad trench penetrating the second insulating layer and the first insulating layer on the first conductive bus bar; and
forming a second conductive bus bar by filling the conductive material into a plurality of the second trench lines, the second connection trench line and the first and the second pad trenches.

10. The method of claim 9, further comprising:
forming a cover layer on the second insulating layer and the second conductive bus bar, wherein a junction hole is formed such that the first and the second pad trenches filled with the conductive material; and
electrically connecting a junction box with the first and the second conductive bus bars through the junction hole.

11. The method of claim 4 further comprising forming a protector at each corner of the photovoltaic substrate, the insulating layer and the cover layer.

12. The method of claim 1, wherein the first and the second trench lines and the insulating layer are simultaneously formed by using a three-dimensional printing technology.

13. A photovoltaic device comprising:
a photovoltaic substrate formed by sequentially stacking a first electrode, a photoelectric conversion layer and a second electrode on a substrate;
an insulating layer being formed on the photovoltaic substrate and comprising a first trench line and a second trench line which have a depth reaching the surface of the second electrode; and
a first conductive bus bar and a second conductive bus bar formed by filling a conductive material into the first and the second trench lines,
wherein at least two photovoltaic cells are included between the first trench line and the second trench line.

14. The photovoltaic device of claim 13, wherein the first and the second trench lines have a depth smaller than the thickness of the insulating layer, and wherein a plurality of trenches are formed on the bottom surfaces of the first and the second trench lines and have a depth reaching the surface of the second electrode.

15. The photovoltaic device of claim 14, wherein a distance between two adjacent trenches among a plurality of the trenches is equal to or more than 1.0 cm and equal to or less than 10 cm.

16. The photovoltaic device of claim 13, further comprising:
a first conductive wire of which one side comes in contact with the first conductive bus bar and the other side is formed on the insulating layer;
a second conductive wire of which one side comes in contact with the second conductive bus bar and the other side is formed on the insulating layer;
a cover layer being formed on the insulating layer, the first and the second conductive bus bars and the first and the second conductive wires, and comprising a junction hole formed on the other sides of the first and the second conductive wires; and
a junction box electrically connected to the first and the second conductive wires through the junction hole of the cover layer.

17. The photovoltaic device of claim 16, comprising a plurality of the first conductive wires which are connected in parallel with each other, and wherein comprising a plurality of the second conductive wires which are connected in parallel with each other.

18. The photovoltaic device of claim 16, wherein vertical cross sectional areas of the first and the second conductive wires are equal to or more than 0.3 mm² and equal to or less than 1.0 mm².

19. The photovoltaic device of claim 16, wherein the first and the second conductive wires include metallic paint or conductive paint comprising any one of ZnO, CNT and graphene.

20. The photovoltaic device of claim 13,
wherein the first trench line further comprises a first extended trench line being formed in the insulating layer, having one side thereof connected to the first trench line and having a depth smaller than the thickness of the insulating layer;
wherein the second trench line further comprises a second extended trench line being formed in the insulating layer, having one side thereof connected to the second trench line and having a depth smaller than the thickness of the insulating layer;
wherein the first and the second conductive bus bars formed by filling the conductive material into the first and the second trench lines and the first and the second extended trench lines;
further comprising:
a cover layer being formed on the insulating layer and the first and the second conductive bus bars and comprising a junction hole formed on the other sides of the first and the second extended trench lines; and
a junction box electrically connected to the first and the second conductive bus bars through the junction hole of the cover layer.

21. The photovoltaic device of claim 20, comprising a plurality of the first and the second extended trench lines.

22. The photovoltaic device of claim 13,
wherein the first trench line further comprises a first pad trench being formed in the insulating layer, having one side thereof connected to the first trench line and having a depth smaller than the thickness of the insulating layer;
wherein the second trench line further comprises a second pad trench being formed in the insulating layer, having one side thereof connected to the second trench line and having a depth smaller than the thickness of the insulating layer;
wherein the first and the second conductive bus bars formed by filling the conductive material into the first and the second trench lines and the first and the second pad trenches;
further comprising:
a cover layer being formed on the insulating layer and the first and the second conductive bus bars and comprising a junction hole formed on the first and the second pad trenches; and
a junction box electrically connected to the first and the second conductive bus bars through the junction hole of the cover layer.

23. The photovoltaic device of claim 13,
wherein the photovoltaic substrate comprises at least two effective areas and the rest of ineffective area;
wherein the insulating layer comprises a first insulating layer and a second insulating layer formed on the first insulating layer;
wherein the first trench lines of which the number is as many as the number of the effective areas are formed in the first insulating layer on the effective areas, wherein the second trench lines of which the number is as many as the number of the effective areas are formed in the second insulating layer on the effective areas;
wherein a first connection trench line connecting a plurality of the first trench lines is formed in the first insulating layer, wherein a second connection trench line connecting a plurality of the first trench lines is formed in the second insulating layer;
wherein the first conductive bus bar is formed by filling the conductive material into the first trench lines and the first connection trench line, wherein the second conductive bus bar is formed by filling the conductive material into the second trench lines and the second connection trench line.

24. The photovoltaic device of claim 23,
wherein the second trench lines further comprise:
a first pad trench being formed in the second insulating layer and having one side thereof connected to any one of the second trench lines; and
a second pad trench penetrating the second insulating layer and having a depth reaching the surface of the first conductive bus bar,
further comprising:
a cover layer being formed on the second insulating layer and the second conductive bus bar, and comprising a junction hole formed on the first and the second pad trenches; and
a junction box electrically connected to the first and the second conductive bus bars through the junction hole.

25. The photovoltaic device of claim 16, wherein the insulating layer includes a curable high polymer.

26. The photovoltaic device of claim 16, wherein the sum of the thicknesses of the insulating layer and the cover layer is equal to or more than 0.3 mm and equal to or less than 5 mm.

27. The photovoltaic device of claim 16, wherein vertical cross sectional areas of the first and the second conductive bus bars are equal to or more than 0.3 mm² and equal to or less than 1.0 mm².

28. The photovoltaic device of claim 16, further comprising a protector formed at each corner of the photovoltaic substrate, the insulating layer and the cover layer.
